(19) United States
(12) Patent Application Publication
(10) Pub. No.: US 2026/0082489 A1
(43) Pub. Date: Mar. 19, 2026

(54) Fully 3D Printed mm-Wave Board Embedded Designs with High Integration Levels

(71) Applicant: NORTHROP GRUMMAN SYSTEMS CORPORATION, FALLS CHURCH, VA (US)

(72) Inventors: Xing Lan, Huntington Beach, CA (US); Arturo J. Mateos, Los Angeles, CA (US); Jesse B. Tice, Torrance, CA (US); Rajinder R. Sandhu, Falls Church, VA (US)

(21) Appl. No.: 18/887,685

(22) Filed: Sep. 17, 2024

(51) Int. Cl. H05K 3/14; B33Y 10/00; B33Y 80/00; H05K 1/16; H05K 3/46

(52) U.S. Cl. CPC H05K 3/14; B33Y 10/00; B33Y 80/00; H05K 1/162; H05K 1/165; H05K 3/4664; H05K 2203/1333

(57) ABSTRACT

A printed circuit board (PCB) that has been fabricated by a 3D printing process. The PCB includes a substrate printed by the 3D printing process, a plurality of stacked dielectric layers printed on the substrate by the 3D printing process, and a plurality of embedded electrical circuit components printed by the 3D printing process on and throughout the substrate and the plurality of dielectric layers. The PCB can be part of a device that operates at millimeter wave frequencies, such as a mm-wave antenna.

### BACKGROUND

### Field

This disclosure relates generally to a printed circuit board (PCB) and, more particularly, to a PCB that has been fabricated by a 3D printing process to include a substrate printed by the 3D printing process, a plurality of stacked dielectric layers printed on the substrate by the 3D printing process, and a plurality of embedded electrical circuit components printed by the 3D printing process on and throughout the substrate and the plurality of dielectric layers.

### Discussion

Mm-wave antennas have a number of high frequency applications. Mm-wave antennas are often fabricated on PCBs. A PCB for a mm-wave antenna typically includes a laminated structure of various dielectric layers that are bonded together. Surface mount technologies (SMT) are then used to bond the various components to the surface of the PCB.

For SMTs, the surface of the PCB is generally formed with tin-lead, silver or gold plated copper pads that do not have holes, known as solder pads, in a predetermined configuration. A solder paste, which is a sticky mixture of solder flux and solder particles or flakes, is deposited on the solder pads by using a stainless steel or nickel stencil and a screen printing process, where it is critical that the solder paste be accurately oriented to the solder pad to prevent short circuits and the like. The PCB is then placed on a conveyor belt to be sent to a pick-and-place machine. The components to be mounted on the PCB are usually delivered to the pick-and-place machine on either a paper/plastic tape wound on a reel or a plastic tube, where large integrated circuits can be delivered to the pick-and-place machine on static-free trays. The pick-and-place machine removes the components from the tape, tube or tray and properly places them on the solder pads on the PCB in a predetermined manner, where the components are held in place by the tackiness of the solder paste. The PCB is then sent to a reflow soldering oven that includes a pre-heat zone, where the temperature of the PCB is gradually and uniformly raised. The PCB then enters a high temperature zone where the temperature is high enough to melt the solder particles in the solder paste, such as 260° C., which bonds the component leads to the solder pads on the PCB. The surface tension of the molten solder helps keep the components in place, and if the solder pad geometries are correctly designed, the surface tension automatically aligns the components on their pads.

The SMT PCB fabrication process discussed above has a number of drawbacks. Those include only being able to mount the circuit components to the surface of the PCB. Further, because the circuit design features of mm-wave antennas are very small, it is difficult to fabricate such PCBs with the resolution required. Also, the fabrication cycle of such PCBs is very long.

### BRIEF DESCRIPTION OF THE DRAWINGS

FIG. 1 is an illustration of an aerosol jet printing machine;

FIG. 2 is a profile view of a PCB fabricated by a 3D printing machine and including embedded capacitors, an embedded inductor and an embedded broad side coupler;

FIG. 3 is an isometric view of a PCB fabricated by a 3D printing machine and including a transformer printed through multiple layers;

FIG. 4 is a profile view of a PCB fabricated by a 3D printing machine and including embedded active components, an embedded inverted MS line, an embedded cavity filter including an air cavity and sub-layers of different materials;

FIG. 5 is a profile view of a mm-wave antenna assembly fabricated by a 3D printing machine and including an embedded Marchand balun and an Archimedean spiral antenna;

FIG. 6 is a top view of the antenna assembly shown in FIG. 5 illustrating the spiral antenna; and

FIG. 7 is a top view of a coaxial feed port that is part of the Marchand balun shown in FIG. 5.

### DETAILED DESCRIPTION OF THE EMBODIMENTS

The following discussion of the embodiments of the disclosure directed to a PCB that has been fabricated by a 3D printing process to include a substrate printed by the 3D printing process, a plurality of stacked dielectric layers printed on the substrate by the 3D printing process, and a plurality of embedded electrical circuit components printed by the 3D printing process on and throughout the substrate and the plurality of dielectric layers is merely exemplary in nature, and is in no way intended to limit the disclosure or its applications or uses.

As discussed above, fabrication of a traditional PCB only allows components and devices to be mounted or assembled on the top or bottom surfaces of the PCB, which creates huge parasitic inductances or loss that harms or limits the design performances. This disclosure describes a 3D printing process for fabricating PCBs that enables printed components, such as capacitors, inductors, antennas, baluns, and other types of components, to be part of the PCB printing process so as to be embedded between and within PCB layers. This is a critical and important capability since all of the components can be placed close to individual functional blocks as needed by design inside the board, rather than being at the top and bottom of the board. The disclosed method allows a fully integrated design and fabrication flow in which the discrete components and PCB itself can be all printed out in one printing flow. This not only reduces the long fabrication time and complexity from conventional PCB fabrication technologies, but also improves the electrical and mechanical performance of the overall board due to reduced or eliminated complex processing steps, parasitics, high temperature soldering, etc. The disclosed method also provides high monolithic integration levels for making the board.

In addition, a 3D printed PCB allows all of the board layers to be printed continuously without etching away the un-used copper or aluminum metallization, therefore, avoiding material waste. Further, the 3D printing process reduces RF parasitics for high frequency applications, simplifies process flow, and enables fully customized designs with unlimited design possibilities. The printing process also reduces the long fabrication time and complexity from conventional board fabrication technologies, and improves the electrical and mechanical performance of the PCB by allowing customized dielectric layer thickness and design configurations. Much finer structures with high resolution can be achieved compared to the traditional PCB fabrication technologies. Examples such as fully printed integrated antenna and Marchand balun embedded with a multilayer 3D PCB are demonstrated to embody the details, merits and approaches of the disclosure. Both active devices, such as amplifiers, and passive components can be integrated inside the PCB and encapsulated by low loss materials during the printing process, providing essentially a reliable monolithic packaging technology. The layers do not have to be uniform thickness. Variable thickness throughout the board process can be accommodated offering many novel design options The disclosed method not only provides low cost, fast turnaround time, and simplified process flow, but also enables new design concepts and implementation methods for microwave wave electronics.

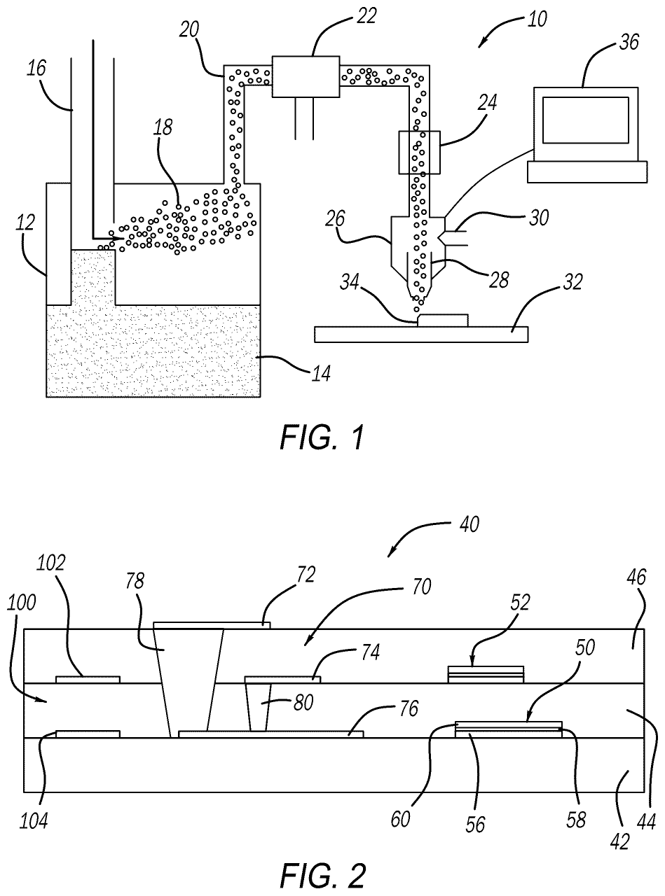

FIG. 1 is a simplified illustration of one suitable example of an aerosol jet printing machine 10 for the purpose of 3D printing PCBs as described herein. It is noted that ink jet printing machines may also be applicable to 3D print the PCBs described herein. The machine 10 includes a container 12 of an ink material 14 that receives an atomizing gas, such as nitrogen, at an inlet 16 to generate an aerosol 18 of the material 14 that is sent through a tube 20. A valve 22 causes the aerosol 18 to become more dense, which is then heated by a heater 24. The heated aerosol 18 is sent to a nozzle 26 that accepts a sheath gas 28 at an inlet 30 for containing the aerosol 18 when it is emitted from the nozzle 26 as a stream and directed onto a substrate 32 to form a printed component 34, where the direction and amount of the aerosol 18 that is emitted out of the nozzle 26 is controlled by a computer 36. The ink material 14 is typically cured by UV light after it is printed. The ink material 14 can be any suitable material for the purposes described herein including various metal conductors, various dielectrics and insulators, various semiconductor materials, various magnetic materials, etc.

FIG. 2 is a profile view of a PCB 40 that has been fabricated by a 3D printing process, such as by the machine 10. The PCB 40 includes a substrate 42, a middle dielectric layer 44 and a top dielectric layer 46 that have been printed by the 3D printing process with the desired material at the desired time consistent with the discussion herein. It is noted that providing two dielectric layers on the substrate 42 is merely for illustration purposes in that many layers can be deposited consistent with discussed herein. As will be described, the 3D printing process fabricates various embedded components within the layers 44 and 46 as the PCB 40 is being printed and fabricated. As the material is being deposited by the printing process, that material can be changed so that the embedded components are printed by the printing process at the desired time and at the desired location.

The PCB 40 includes two embedded capacitors 50 and 52, where the capacitor 50 is printed on and after the substrate 42 has been printed and the capacitor 52 is printed on and after the layer 44 has been printed. The capacitor 50 includes a bottom metal layer 56 printed on the substrate 42 by the printing process, a very thin dielectric layer 58 printed on the metal layer 56 by the printing process and a top metal layer 60 printed on the dielectric layer 58 by the printing process, where the dielectric material of the layer 58 would be a high-k dielectric and would be of a different material than the dielectric material of the layers 44 and 46. After the capacitor 50 has been printed as described, the dielectric layer 44 is printed over and around the capacitor 50. Likewise, the capacitor 52 includes a printed bottom metal layer, a printed dielectric layer and a printed top metal layer, where the dielectric layer 46 is printed over and around the capacitor 52.

The PCB 40 also includes a stacked spiral inductor 70 formed on and through the layers 44 and 46. The inductor 70 would include multiple layers of shaped metal, or another conductor, illustrated as layers 72, 74 and 76, where each of the layers 72, 74 and 76 has a certain shape, such as round, square, etc., that are connected by metal vias 78 and 80 through the dielectric layers therebetween.

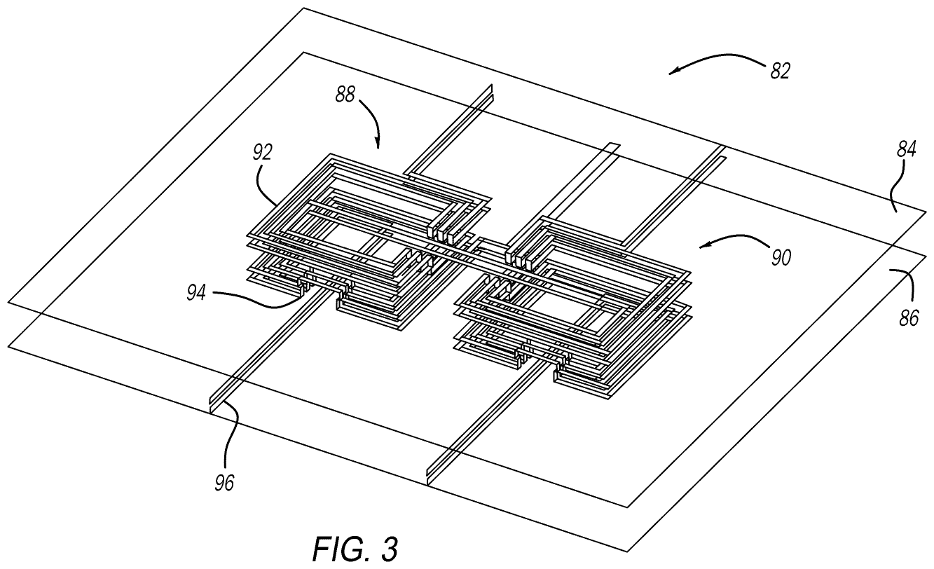

FIG. 3 is an isometric view of a balun or transformer 82 that has been 3D printed as described through multiple printed dielectric layers represented by layers 84 and 86. The transformer 82 includes a primary coil 88 and a secondary coil 90 both having concentric square conductors 92 printed on multiple layers and vias 94 coupling the conductors 92 on the different layers through the dielectric layers, where the conductors 92 are coupled to feed ports 96.

The PCB 40 also includes a broad side coupler 100 printed in the layers 44 and 46 as represented by a conductive layer 102 printed on the substrate 42 and covered by the layer 44 and a conductive layer 104 printed on the layer 44 and covered by the layer 46.

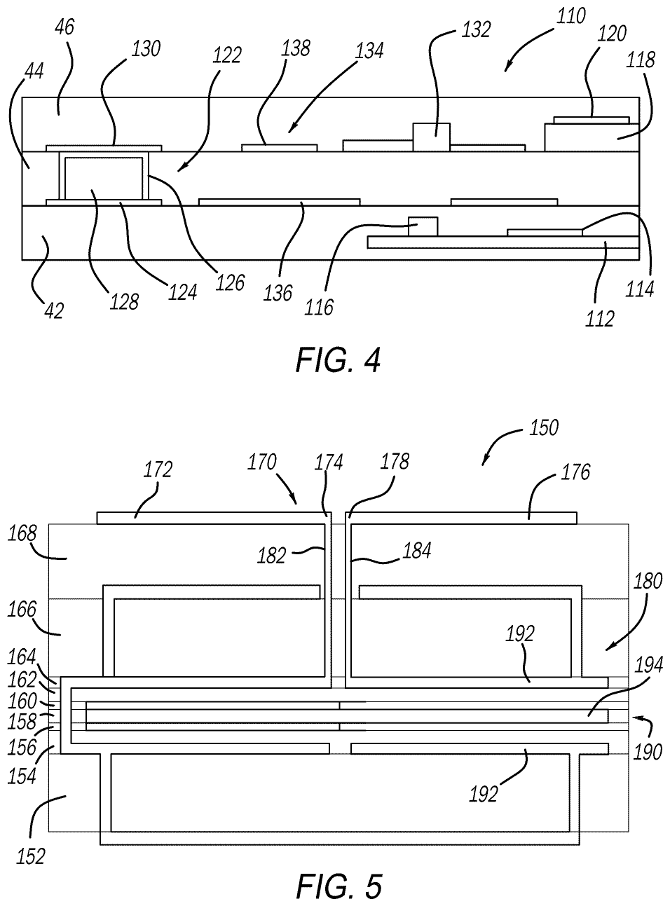

The PCB 40 includes a few of the electrical components that can be 3D printed as described. FIG. 4 is a profile view of a PCB 110 illustrating other printed electrical components, where the PCB 110 also includes the substrate 42, the middle dielectric layer 44 and the top dielectric layer 46. The 3D printing process allows thinner sub-layers of different materials, such as magnetic materials, different dielectric materials, etc., to be formed within the thicker layers 42, 44 and 46. This is illustrated by a sub-layer 112 printed within the substrate 42 and having electrical components 114 and 116 printed thereon. The printing process prints the substrate 42 to a certain thickness, then prints the sub-layer 112 on the partially printed substrate 42 to a certain thickness and at the desired location using a different ink material, then prints the components 114 and 116 on the sub-layer 112 using yet another different ink material, and then prints the rest of the substrate 42 over the sub-layer 112 and the components 114 and 116 to the desired thickness. The PCB 110 also includes a sub-layer 118 printed on the layer 44 and a component 120 printed on the sub-layer 118, where the layer 46 is then printed over the layer 44, the sub-layer 118 and the component 120.

Various types of cavity filters, oscillators, resonators, etc. that require an air cavity can also be 3D printed as part of the PCB 110. This is illustrated by a cavity filter 122 that includes a metal contact layer 124 printed on the substrate 42. A U-shaped structure 126 made of a suitable material, such as aluminum, is bonded to the contact 124 by, for example, glue, so as to define an air cavity 128. The layer 44 is then printed around the structure 126 and over the contact 124. A top contact layer 130 is then printed on the structure 126 and the layer 46 is printed over the contact 130.

The PCB 110 also includes embedded active components 132 printed on the layer 44 and an embedded inverted MS line 134 including a conductive layer 136 printed on the substrate 42 and a conductive layer 138 printed on the layer 44.

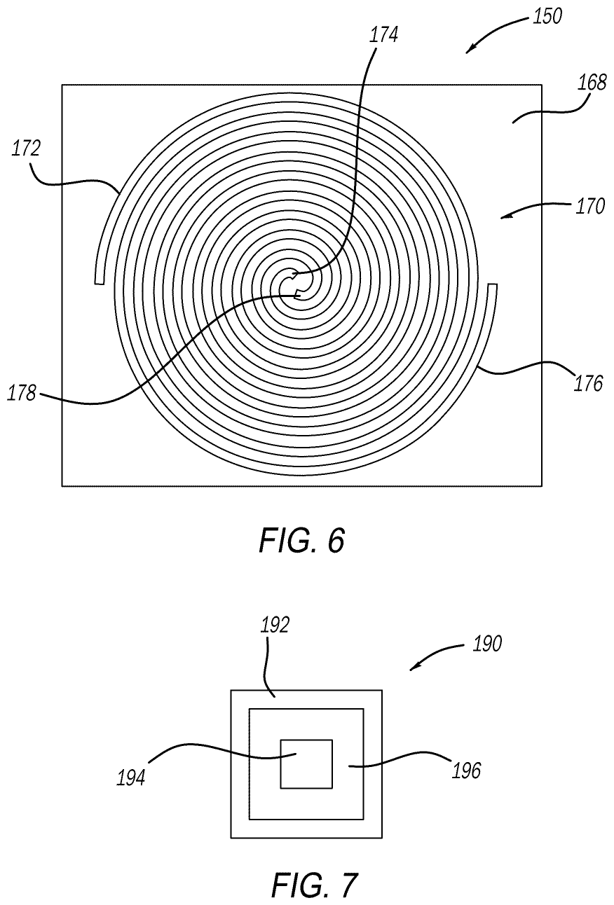

FIG. 5 is a profile view and FIG. 6 is a top view of a mm-wave antenna assembly 150 printed on and through nine dielectric layers 152, 154, 156, 158, 160, 162, 164, 166 and 168 of varying thicknesses suitable for the antenna assembly 150, where the thickness of the layers 154-164 is much thinner than the thickness of the layers 152, 166 and 168. The antenna assembly 150 includes a wideband Archimedean spiral antenna 170 printed on the layer 168 using a conductive ink and having a spiral arm 172 with a center feed point 174 interwoven with a spiral arm 176 with a center feed point 178. The antenna assembly 150 also includes a Marchand balun 180 printed on and through the layers 152-168, as shown, that provides impedance matching between the antenna 170 and radio circuitry (not shown) in a manner well understood by those skilled in the art. The balun 180 includes a square coaxial feed port 190 having an outer conductor 192 printed on and through the layers 152-164 and an inner conductor 194 printed on and through the layers 156-160, as shown, to which the radio circuitry is coupled. The outer conductor 192 is electrically coupled to the feed points 174 and 178 by balanced twin feed vias 182 and 184, respectively, that are printed through the layers 166 and 168. FIG. 7 is a top view of the feed port 190 showing the outer conductor 192 electrically separated from the inner conductor 194 by a dielectric region 196.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A printed circuit board (PCB) that has been fabricated by a 3D printing process, said PCB comprising:
a substrate printed by the 3D printing process;
a plurality of stacked dielectric layers printed on the substrate by the 3D printing process; and
a plurality of embedded electrical circuit components printed by the 3D printing process on and throughout the substrate and the plurality of dielectric layers.

2. The PCB according to claim 1 wherein the plurality of embedded electrical components are part of a device that operates at millimeter wave frequencies.

3. The PCB according to claim 1 wherein the plurality of embedded electrical components include an antenna and a balun.

4. The PCB according to claim 3 wherein the antenna is a spiral antenna including two spiral arms printed on a top dielectric layer and the balun is a Marchand balun printed throughout several of the dielectric layers.

5. The PCB according to claim 4 wherein the plurality of stacked dielectric layers is nine dielectric layers of different thicknesses.

6. The PCB according to claim 1 wherein the plurality of embedded electrical components include a transformer having a primary coil and a secondary coil printed through multiple dielectric layers.

7. The PCB according to claim 1 wherein the plurality of embedded electrical components include a spiral inductor printed through multiple dielectric layers.

8. The PCB according to claim 1 wherein the plurality of embedded electrical components include a capacitor.

9. The PCB according to claim 1 wherein the plurality of embedded electrical components include a cavity filter having a cavity structure bonded to one or more of the dielectric layers.

10. The PCB according to claim 1 wherein the plurality of dielectric layers include at least one dielectric sub-layer printed within a thicker dielectric layer that is made of a different dielectric material than the thicker dielectric layer.

11. A method for fabricating a printed circuit board (PCB) by a 3D printing process, said method comprising:
printing a substrate by the 3D printing process;
printing a plurality of stacked dielectric layers on the substrate by the 3D printing process; and
printing a plurality of embedded electrical circuit components by the 3D printing process on and throughout the substrate and the plurality of dielectric layers.

12. The method according to claim 11 wherein the plurality of embedded electrical components are part of a device that operates at millimeter wave frequencies.

13. The method according to claim 11 wherein the plurality of embedded electrical components include an antenna and a balun.

14. The method according to claim 13 wherein the antenna is a spiral antenna including two spiral arms printed on a top dielectric layer and the balun is a Marchand balun printed throughout several of the dielectric layers.

15. The method according to claim 14 wherein the plurality of stacked dielectric layers is nine dielectric layers of different thicknesses.

16. The method according to claim 11 wherein the plurality of embedded electrical components include a transformer having a primary coil and a secondary coil printed through multiple dielectric layers.

17. The method according to claim 11 wherein the plurality of embedded electrical components include a spiral inductor printed through multiple dielectric layers.

18. The method according to claim 11 wherein the plurality of embedded electrical components include a capacitor.

19. The method according to claim 11 wherein the plurality of embedded electrical components include a cavity filter having a cavity structure bonded to one or more of the dielectric layers.

20. The method according to claim 11 wherein the plurality of dielectric layers include at least one dielectric sub-layer printed within a thicker dielectric layer that is made of a different dielectric material than the thicker dielectric layer.
